(19) United States
(12) Patent Application Publication
(10) Pub. No.: US 2015/0115716 A1
(43) Pub. Date: Apr. 30, 2015

(54) Method for Recording Power Consumption Data of a Residential Unit and Method for Controlling a Residential Unit

(71) Applicant: aizo group ag, Schlieren (CH)

(72) Inventors: Martin Vesper, Wuppertal (DE); Cornel Durrer, Hünenberg See (CH)

(21) Appl. No.: 14/391,467

(22) PCT Filed: Apr. 12, 2013
(86) PCT No.: PCT/EP2013/057708

§ 371 Date: Oct. 9, 2014

(30) Foreign Application Priority Data
Apr. 12, 2012 (EP) PCT/EP2012/056646

(51) Int. Cl. G01R 21/00; H02J 3/00

(52) U.S. Cl. CPC G01R 21/00; H02J 3/00
USPC 307/31; 29/825; 324/76.11

(57) ABSTRACT

A method for recording power consumption data of a residential unit, the residential unit having a distributor (4) with at least one load circuit (7), wherein at least one load (9) is arranged in each load circuit (7), wherein at least one load (9) can be individually actuated and wherein at least one load circuit (7) has means (6) for measuring the power consumed in the load circuit (7). The residential unit has a control unit (10), which actuates the load or loads (9) on the basis of predetermined or predeterminable scenes. The power consumption of the load circuits (7) is measured individually and recorded by the control unit (10) and the control unit (10) assigns the power consumption to the set scenes.

The present invention relates to a method for recording power consumption data of a residential unit, to a method for controlling a residential unit, to a computer program product and to a method for equipping or retrofitting residential units, with the result that power consumption data can be recorded, according to the precharacterizing clauses of the independent claims.

The prior art discloses various methods and apparatuses which make it possible to record the power of individual loads or of an entire residential unit. In addition, methods which allow remote access to the heating system of a holiday home, for example, are known.

For example, US 2009/0195349 A1 shows a system and a method for monitoring the energy consumption of home applications. For this purpose, measuring means are arranged in the individual sockets, in multiple sockets or in the individual loads, which measuring means determine the energy consumption of the connected loads or of the load directly and transmit it to a central base unit. The energy consumption can be represented on the basis of these measured data relating to the loads. However, it is disadvantageous that each load itself must have a measuring means or must be connected to a socket having a corresponding measuring means. If a load is connected directly without a corresponding measuring means, its consumption cannot be determined and taken into account. In addition, each measuring means must be individually addressable in order to be accordingly detected and addressed in the system.

EP2012132A1 discloses an apparatus for identifying and measuring the energy consumption of an electrical load, with the result that individual cost accounting can be created for each load. The energy consumption of freely selectable load groups can also be recorded, in which case these load groups do not have to be arranged in the same circuit. However, a particular behavior of the user cannot be inferred from these consumption data.

EP2012468A2 shows a method for automatic scene selection during a switching operation of a scene-typical load. For this purpose, a typical load is defined for a particular scene and triggers the scene associated with it when actuated. Monitoring of the consumption data is not provided.

WO2011/039334A2 describes a method and an apparatus for transmitting data in an AC voltage network, the transmitter impressing a signal on the AC voltage network using a current source. This signal can be read at the receiver end using a shunt.

WO2011/038912A1 shows an apparatus for modifying an AC voltage and a method for transmitting data using a modified AC voltage. For this purpose, the AC voltage is modified directly in the distribution box in a domestic installation in such a manner that a signal can be transmitted from a transmitter arranged in the distribution box to a receiver, for example in a load. It is therefore possible, for example, for loads to be controlled by a central unit and for predefined scenes to be switched.

The object of the invention is to overcome the disadvantages of the prior art. In particular, the power consumption is intended to be determined and to be able to be easily monitored in a form comprehensible to the user.

This object is achieved by means of the methods and the computer program product defined in the independent patent claims. Further embodiments emerge from the dependent patent claims.

Formulations such as “A and/or B” are understood below as meaning the following possible combinations: A or B, A, A not B, B, B not A, A and B, A xor B.

The term “recording power consumption data” is understood as meaning, on the one hand, the direct measurement of the power consumption of a load circuit in the distribution box, for example; however, a power consumption of a load circuit, for example, can also be determined, on the other hand, by the sum of the individually measured consumptions of the loads connected to the corresponding load circuit.

The term “residential unit” is not intended to be reduced to apartments or apartment buildings below. Rather, from the point of view of the power supply, a residential unit is understood as meaning a unit which has its own power distributor. For example, such a residential unit comprises a single-family house, an individual apartment in an apartment building, an office unit having a plurality of individual offices in an office complex, a workshop, an entire building or a section of a building or a warehouse. However, a residential unit can also likewise be understood as meaning a vehicle, a train, a ship or an aircraft.

In a building power supply system, a load circuit of a residential unit as described above is understood as meaning that part of the building power supply system, starting from the system access, which branches off from the distributor and leads to one or more loads. If there is no load in a circuit, for example in an empty room without a lamp, this is not a load circuit in the sense of the invention. For example, a load circuit comprises all system sockets with connected loads as well as the switches and lamps in a room. Each load circuit usually has its own fuse, with the result that, in the event of damage, only a system failure occurs in the corresponding load circuit and the entire residential unit is not disconnected from the system. In this case, the term “building power supply system” should be understood as meaning a synonym for building power supply systems and similar cabling arrangements, in particular also for electrical systems in vehicles, trains, ships and aircraft.

A load is understood as meaning any device which consumes electrical power during operation. Examples are lamps, a TV, a radio, a fan, an air-conditioning system, a heating device, a printer, a monitor, a computer, electric blinds, a washing machine, a dishwasher, a cooker, a refrigerator, a coffee machine, a toaster, a vacuum cleaner, etc.

Control is understood as meaning, for example, direct switching-on or switching-off, dimming, lowering or raising the volume, switching to the standby mode, opening or closing of one or more loads or transferring a corresponding control signal to a suitable switching means assigned to the load.

Electrical power is the power drawn or delivered as electrical energy per time. The power is measured in watts. Since the power of one or more loads is of interest below, the term “power consumption” is used for the power drawn by the load.

Within the scope of the invention, a scene is understood as meaning a circuit state of at least one controllable load, preferably a plurality of or all controllable loads, of a residential unit or of sections of a residential unit on the basis of predefined or predefinable situations or activities.

Calling a scene means the general addressing of all controllable loads or their associated switching means, each load or its associated switching means knowing its expected behavior and adjusting the power consumption according to the called scene. This may relate to all luminaires in a room, for example, or else all loads in an installation and may also apply to subsequently inserted loads. They may already know a standard behavior and react accordingly when a scene is called.

Room-related scenes, for example lighting or shading atmospheres, or global scenes for the entire installation, for example coming, going, ringing, panic, sleeping, waking up etc., can be called by a user. These scenes can be called by automatic machines when particular situations occur in order to indicate presence, for example, or to automatically switch the light at dusk. Scenes can also be called by a user, in particular on the basis of his activity. In this case, the scenes typically depict user habits. For example, a “television” scene may be defined, which switches on the TV, switches background lighting to 100%, dims the ceiling lighting in the living room to 50%, closes the blind and does not further influence the other loads in the residential unit. A “going” scene may mean, for example, completely switching off the loads in the residential unit, in which case individual loads, for example a refrigerator, are also not influenced by this scene. At the same time as the loads are switched off, the “going” scene may also activate an alarm system, for example. A “panic” scene may be defined, for example, in such a manner that all luminaires in the residential unit go on to their maximum brightness in this case, while other loads are not influenced. In this case, a scene is not tied to a load circuit. A scene does not comprise a predefined number of loads but rather actually all loads in the residential unit, in which case only the status of individual loads is influenced by the scene. It goes without saying that the individual scenes can be arbitrarily named.

In a method according to the invention for recording power consumption data of a residential unit, the power consumption of the load circuits is individually measured and recorded by a monitoring unit. The monitoring unit assigns the power consumption determined in this manner to the scenes which have been set. In this case, the residential unit has a distributor with at least one load circuit. At least one load is arranged in each load circuit, at least one load of the residential unit being individually controllable. At least one load circuit has means for measuring the power consumed in the load circuit. In addition, the residential unit has a monitoring unit which controls the load(s) on the basis of predetermined or predeterminable scenes. In this case, the controlled loads need not be known to the monitoring unit. For example, a load may be configured in such a manner that it switches off in a “going” scene and/or automatically switches to its full power in a “panic” scene. The measurement of the power consumption can be easily assigned to the scene which has been set. It now becomes possible, for example, to accurately analyze the power consumption of a scene, for example “television”, as described above, and to assign a power consumption to this scene. This assignment becomes possible as a result of a temporal correlation of the control of the new scene and the corresponding change in the power consumption of the residential unit. It is therefore possible to identify so-called “power guzzler” scenes and possibly avoid or optimize them. For example, a conventional bulb can be replaced with an LED luminaire.

The predetermined or predeterminable scenes are stored in a monitoring unit. These stored scenes can in turn be selected and retrieved in the monitoring unit. In this case, the scenes can be directly selected by the monitoring unit, for example using a preprogrammed or preprogrammable temporal sequence, or can be selected from the outside using an actuating unit. The actuating unit may be, for example, a pushbutton which is connected to the monitoring unit. Such a pushbutton can be arranged directly in a load circuit or is connected or can be connected to the monitoring unit via radio or other transmission channels, for example.

The monitoring unit may be in the form of an independent element, may be integrated in a router, may be reproduced in one or more of the means for measuring the powers consumed in the load circuits, may be reproduced in a PC which is connected or can be connected to the measuring means, etc.

In accordance with an assignment of a particular scene to a power consumption, a change in the power consumption can also be assigned to a change in the scene. For example, it is possible to detect a change from the “television” scene to a “reading” scene in which only a floor lamp at the sofa is operating. The user therefore discerns, for example, that almost twice as much power is consumed for the “television” scene than for the “reading” scene.

The scenes can be set across the load circuits. A “television cold” scene, for example, may comprise not only the loads of the “television” scene which are assigned to the same load circuit but also an air-conditioning device which has a separate three-phase electrical connection to 400 V. For example, a fan which is connected to another load circuit, in particular in another room, via an extension cable could also be assigned to the “television cold” scene.

The power consumption of the individual scenes and/or their sum can be represented graphically and/or in the form of text. Different representation possibilities are conceivable for this purpose; for example, a simple time/power diagram may be recorded. The individual active scenes may also be represented in real time, for example, as circles with their size in relation to the current power consumption. It goes without saying that other types of representation are also conceivable.

Here and below, representation in the form of text is also understood as meaning a notification in the form of a push message.

A change in the power consumption can be graphically represented with a message relating to the changed scene. If, for example, the “television” scene is switched off, a corresponding drop in the power curve by 260 W can be additionally labeled with a message, for example in the form of a speech bubble “television off, −260 W”. A change from the “television” scene with 260 W to “reading” with 100 W can then be represented, for example, by “television off, reading on, −160 W”. In addition, different colors can be used to indicate a power increase or power reduction.

In addition to the power consumption of the load circuits, the power consumption of the individual loads can also be recorded. For this purpose, the loads may have an internal or external switching means which directly records the power and transmits it to the monitoring unit. It goes without saying that other possible ways of recording the power of the individual loads are also conceivable. In this case, data can be transmitted in a wired manner directly via the power line, for example as described in WO2011/039334A2, or via any other transmission medium.

The power consumption of the individual loads can also be represented graphically and/or in the form of text. If the power consumption of the loads is determined, the power consumption of a scene can be easily optimized. For example, it is possible to discern that the greatest power consumption comes from the ceiling lighting in the “television” scene. The user can therefore decide whether the “television” scene is intended to be optimized by dimming the ceiling lighting to 50%, for example, or even switching it off entirely. Furthermore, replacement of conventional incandescent means with LEDs is conceivable. It is likewise possible to discern when an additional load, for example a reading lamp, is also manually connected for the “television” scene. The changed measured power consumption can be designated accordingly, for example with a speech bubble “reading lamp on, living room, +50 W”. If a load which is unknown up until now is connected, this can be labeled, for example, “unknown load on, living room, +75 W”. It is conceivable for a new load to have already been preset in such a manner that it already recognizes the “going” and “panic” scenes or other scenes defined as standard and behaves accordingly when these scenes are called. The power consumption of the load circuit can be determined and assigned to a scene irrespective of whether or not all loads are known. If the unknown load is provided with a switching means for recording its power consumption, this measured power consumption can also be transmitted to the monitoring unit. If no such switching means is present, the power consumption of the scene is determined in the load circuit. The power consumption of the unknown load can then be determined, for example, from the difference between the current power consumption and a previously determined power consumption of the scene.

The consumption data of the residential unit, in particular the power consumption of the individual load circuits and/or of the individual loads and/or of the individual scenes, can be transmitted from the monitoring unit to an external device, in particular via the Internet. The consumption data can therefore be controlled, monitored, represented, analyzed and/or processed further in an external device. For example, cost accounting can be created thereby on the basis of the individual scenes and/or the individual loads. Devices such as smartphones, tablet PCs or other devices can also be connected by means of a connection to the Internet. The user therefore has access to the consumption data of his residential unit at any time irrespective of his location. It goes without saying that the monitoring unit must be connected to the Internet for this purpose. For example, the monitoring unit can be integrated in a known router or can be installed as a software package or app in the router or an independent computer. It is likewise conceivable, for example, for a network operator to be able to use such data for capacity planning.

The consumption data may also be represented graphically and/or in the form of text, in particular as described above, on the external device.

A method according to the invention for controlling, in particular remotely controlling, a residential unit involves controlling a monitoring unit, the monitoring unit being connected or being able to be connected to a control device, in particular via the Internet, individual scenes being selected and the loads in the residential unit being controlled accordingly. In this case, the residential unit has a distributor with at least one load circuit. At least one load is arranged in each load circuit, at least one of these loads being individually controllable. At least one load circuit has means for measuring the power consumed in the load circuit. The residential unit also has a monitoring unit which controls the loads on the basis of predetermined or predeterminable scenes. Accordingly, a control device, for example a smartphone, a tablet PC or a pushbutton, can select scenes by accordingly controlling the loads of a residential unit.

Here and below, controlling a residential unit is understood as meaning the fact that individual scenes are selected and the loads are controlled according to the selected scene. Controlling is likewise also understood as meaning directly switching on/switching off or dimming individual loads and setting or modifying a scene.

The power consumption of the load circuits can be individually measured and recorded by the monitoring unit. The monitoring unit can assign the measured power consumption to the scenes which have been set and are therefore known. This makes it possible to compare scene-specific power consumptions. The user can change his behavior to a more economical behavior.

It is also conceivable for the power consumption of the individual loads to be individually recorded and transmitted to the monitoring unit.

The consumption data of the residential unit, in particular the power consumption of the individual load circuits and/or of the individual loads and/or of the individual scenes, can be transmitted from the monitoring unit to the control device. Accordingly, not only is control from the control device possible, but rather the consumption data can also be analyzed in the control device. Corresponding software or an app, for example, can be installed on the control device for this purpose. If the consumption data are made available to a network operator, the latter can prevent capacity bottlenecks or power peaks, for example, by deliberately switching off or blocking scenes and/or loads.

The consumption data can be represented graphically and/or in the form of text, in particular as described above, on the control device. It is conceivable for the user to represent and visualize the consumption data in a manner corresponding to his requirements or preferences.

At least one scene can be configured using the control device. It is therefore conceivable for not only the predefined scenes to be able to be selected and triggered but also for load settings to be able to be added to or removed from a scene or for the power consumption of the loads to be able to be adapted. All possibilities for optimizing his power consumption are available to the user.

A computer program product according to the invention can be loaded directly into the internal memory of a digital computer and comprises software sections which can be used to carry out the steps as described above when the product runs on a computer. Such computer programs may be downloaded, for example, onto a smartphone or a tablet PC from the Internet as an app. The computer program product allows the residential unit to be controlled using preset scenes. However, the individual scenes may also be modified and/or individual loads may be controlled. In addition, a graphical representation of the power consumption data is conceivable. Such a computer program product can be programmed by a person skilled in the art in a manner known per se in conventional programming languages.

A method according to the invention for equipping or retrofitting residential units, with the result that the methods as described above can be carried out, comprises one or more of the following steps in any desired combination:
installing controllable switching means in one or more loads and/or installing controllable loads,
installing means for measuring consumed power in one or more load circuits,
installing a monitoring unit which is configured in such a manner that the monitoring unit controls the loads on the basis of predetermined or predeterminable scenes and records the power consumption of the load circuits and/or of the loads and assigns it to the scenes which have been set.

The invention is explained in more detail below using figures which illustrate only exemplary embodiments. In the drawing:

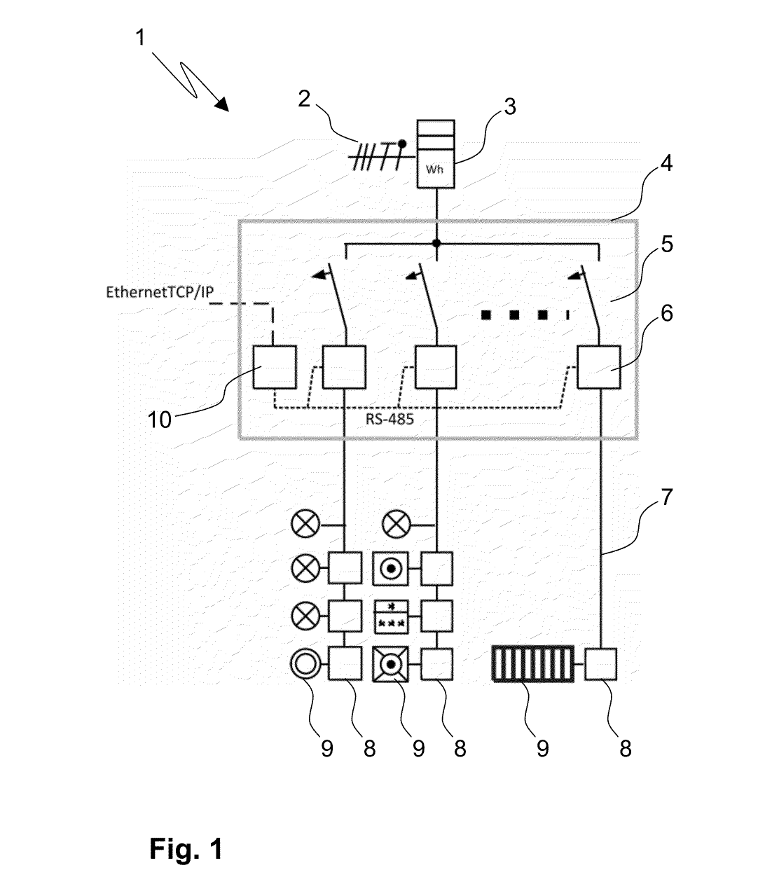

FIG. 1: shows a building power supply system for carrying out the method according to the invention,

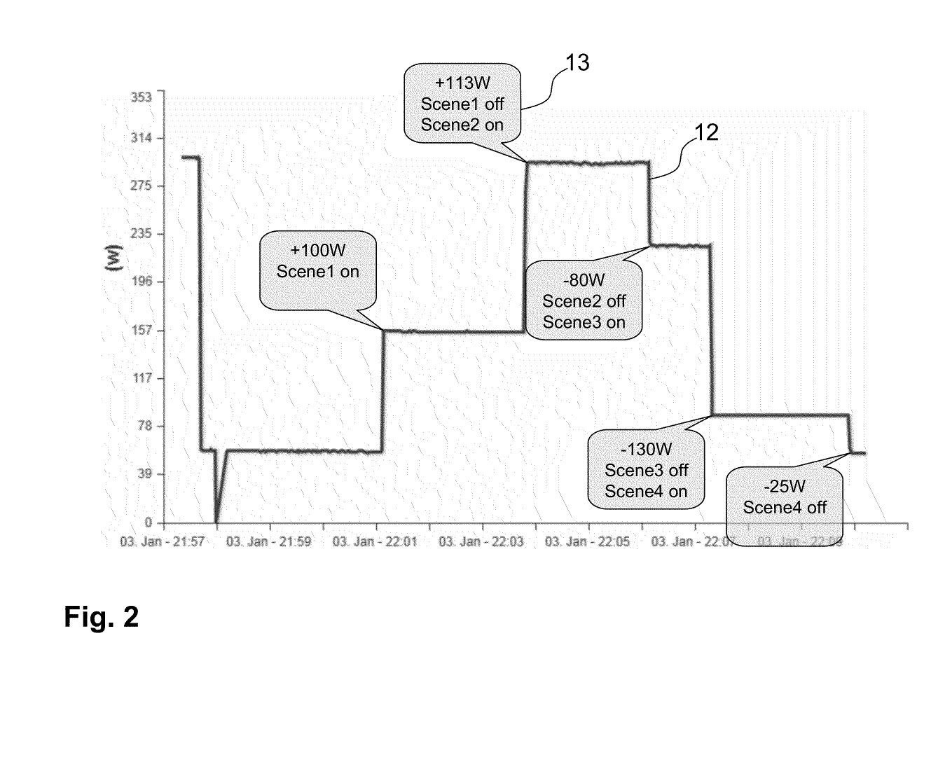

FIG. 2: shows a time/power diagram of the instantaneous power consumption of the building power supply system,

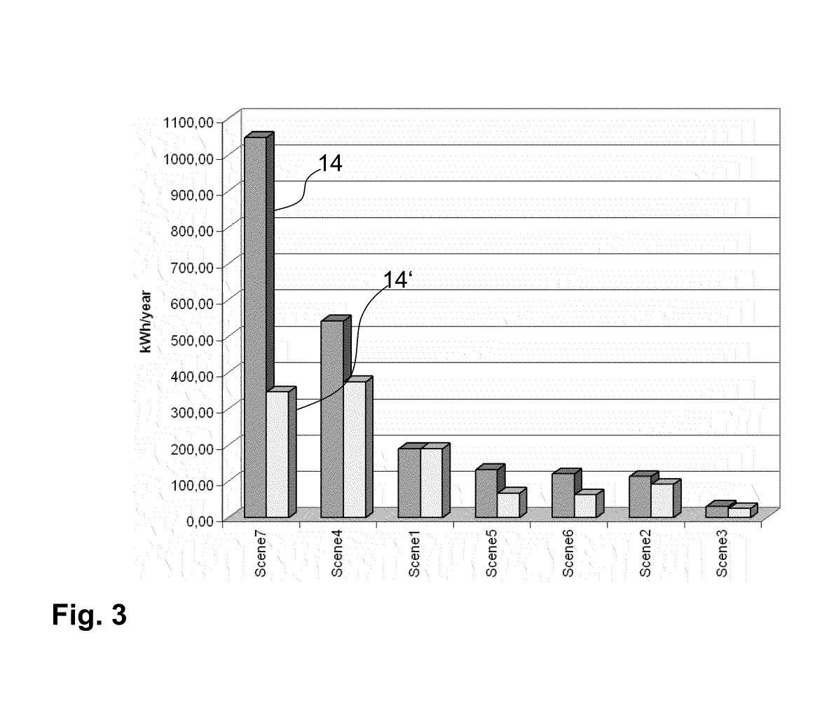

FIG. 3: shows a bar chart of the consumed energy per scene used, and

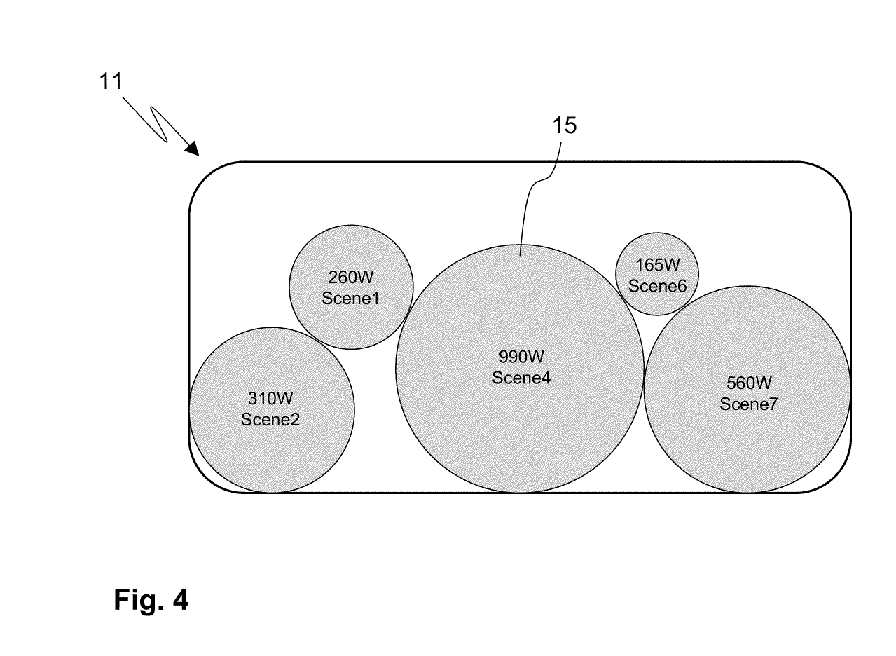

FIG. 4: shows an illustration of the instantaneous power consumption in a spherical diagram on a control device.

FIG. 1 illustrates a building power supply system 1 for carrying out the method according to the invention. Starting from a system access 2 with an electricity meter 3, a distributor 4 is situated in the building. In this distributor 4, the AC voltage network is divided among the individual load circuits 7, each load circuit 7 having its own fuse 5 and a measuring means 6 in the form of an electricity meter for measuring the power consumed in the load circuit 7. In conventional building cabling, each load circuit 7 corresponds approximately to one room, in which case individual devices, for example an oven, a washing machine or an electrical heating system, usually have their own load circuit. In each load circuit, loads 9 are connected either directly or via a controllable switching means 8.

The measuring means 6 are connected to one another via an RS-485 bus. A monitoring unit 10 is also additionally arranged in the distributor 4 and is likewise connected to the individual measuring means 6 of the load circuits 7. Each measuring means 6 transmits the measured power consumption in its load circuit 7 to the monitoring unit 10 in real time via the RS-485 bus. It goes without saying that, instead of an RS-485 bus, another data connection can also be used. The monitoring unit 10 has a connection for an Ethernet or to the Internet, with the result that the monitoring unit 10 can be connected to external devices. The individual controllable switching means 8 and/or the loads 9 themselves are equipped in such a manner that they can determine their power consumption themselves and can transmit it to the measuring means 6 of their load circuit 7. The measuring means 6 therefore has the possibility of transmitting the self-measured value of the power consumption to the monitoring unit 10 and/or of forwarding the sum of the individual values and/or the individual values which have been transmitted from the loads 9 or controllable switching means 8.

So-called scenes are now stored in the monitoring unit 10 or in the individual measuring means 6. These scenes can be selected by a control device or by a pushbutton and can then be called by the monitoring unit. For example, the monitoring unit 10 can call a first “television” scene which switches on the TV, dims background lighting to 50% and dims the ceiling lighting in the living room to 80%. In this case, not all loads 9 have to be arranged in the same load circuit 7. For example, the TV and the background lighting can be assigned to a first load circuit 7, whereas the ceiling lighting is assigned to a second load circuit. Accordingly, the measuring means 6 of the first and second load circuits record the power consumption of the “television” scene with 160 W in the first load circuit and with 100 W in the second load circuit. These two values are transmitted to the monitoring unit 10 which sums the power consumption and assigns 260 W to the first “television” scene. Further scenes, for example “reading on the sofa”, “reading in bed”, “cooking”, “eating”, “romantic dinner”, “working in the office”, etc., can now be defined in a similar manner. Each individual scene call will then switch the corresponding loads 9 in the individual load circuits 7 on or off or, in the case of a luminaire, will dim it to a particular brightness. The power consumption is respectively recorded for each load circuit 7 independently of the individual loads 9 and is transmitted to the monitoring unit 10 which assigns it to the individual scenes which have been set. Alternatively or additionally, the power consumption for each load 9 can also be recorded and can be transmitted to the monitoring unit 10. The power consumptions can be considered individually and/or in summed form, that is to say for each load 9, for each load circuit 7, for each scene or for each residential unit 1, and can be represented on a display, for example.

FIG. 2 shows a time/power diagram of the instantaneous power consumption 12 of the building power supply system 1. In this case, the ongoing time is plotted on the x axis and the power consumption is plotted on the y axis. The curve of the power consumption 12 is continuously updated in real time and each change in the power consumption is commented on using a status message 13. The user therefore immediately knows the cause of the changed power consumption. It goes without saying that the consumption curve illustrated is only one example of the countless representation possibilities and other types of representation are also conceivable. In particular, other status messages are also conceivable; for example, it is possible not only to reveal a change in the power consumption but also to respectively represent all activated scenes. In this case, the text in the status messages can be configured in any desired manner and the individual scenes can be arbitrarily named.

The time/power diagram shown can be represented on a permanently installed device directly in the residential unit, for example in the living room. For this purpose, this device is directly connected to the monitoring unit 10 (see FIG. 1) or the monitoring unit 10 directly has a display for displaying the time/power diagram. Alternatively, the time/power diagram shown can also be displayed on a portable device, for example on a smartphone, a tablet PC or a notebook. The connection to the monitoring unit is then preferably carried out via the Internet.

FIG. 3 illustrates a bar chart of the energy 14, 14′ consumed per scene used and per year. This is a further form of representation for visualizing the power consumption. It goes without saying that the individual scenes can be individually labeled. The user immediately discerns which scene consumes most energy 14 over the year. This energy consumption results, on the one hand, from the period of time in which the corresponding scene is used and from the power consumption of the scene. The user can therefore consider whether the usage duration of the corresponding scene is actually required or whether the power consumption of the scene can be optimized. For example, the power consumption of a scene can be reduced by skillfully switching off individual loads or by replacing a halogen lamp with an LED luminaire. A change in the scene may be represented directly in the bar chart by means of a projected energy consumption 14′, for example. For example, scene7 exhibits a reduction in the annually consumed energy from 1050 kWh to 350 kWh only by replacing halogen luminous means with new LED luminous means.

FIG. 4 shows an illustration of the instantaneous power consumption of a residential unit in a circle diagram on a control device 11. The control device is a smartphone, a tablet PC or a notebook computer, for example. The instantaneous power consumption of the scenes used is represented directly by the size of the circles 15. The user immediately discerns which scenes are active in the residential unit and accordingly contribute to the total power consumption of the residential unit. The actual value may additionally also be entered. The user also discerns at a glance which scene causes the greatest power consumption and can have an influence if necessary. In the example shown, scene4 consumes 990 W. It goes without saying that the individual scenes can be individually labeled. For example, instead of “Scene4”, scene4 can also be labeled “working in the office”. Detailed information relating to this scene, such as the individual loads 9 (see FIG. 1) with the corresponding power consumption, can be represented by selecting the corresponding scene, for example. Loads which are not required can be excluded from the scene or their consumption can be reduced. For example, luminaires could be dimmed. It therefore becomes possible to efficiently monitor and directly influence the power consumption of the individual scene and of the entire residential unit.

1-15. (canceled)

16. A method for recording power consumption data of a residential unit,
the residential unit having a distributor with at least one load circuit,
at least one load being arranged in each load circuit,
at least one load circuit having means for measuring the power consumed in the load circuit,
the residential unit having a monitoring unit which controls the load(s) on the basis of predetermined or predeterminable scenes,
at least one load being individually controllable,
the power consumption of the load circuits being individually measured and recorded by the monitoring unit, and the monitoring unit assigning the power consumption to the scenes which have been set.

17. The method as claimed in claim 16, wherein a change in the power consumption is assigned to a change in the scene.

18. The method as claimed in claim 16, wherein the scenes can be set across the load circuits.

19. The method as claimed in claim 16, wherein the power consumption of at least one of the individual scenes or their sum is represented at least one of graphically or in the form of text.

20. The method as claimed in claim 19, wherein a change in the power consumption is graphically represented with a message relating to the changed scene.

21. The method as claimed in claim 16, wherein the power consumption of the individual loads is recorded.

22. The method as claimed in claim 16, wherein consumption data of the residential unit are transmitted from the monitoring unit to an external device.

23. The method as claimed in claim 22, wherein the consumption data of the residential unit are transmitted via the Internet.

24. The method as claimed in claim 22, wherein the consumption data of the residential unit comprises the power consumption of at least one of the individual load circuits or the individual loads or the individual scenes.

25. The method as claimed in claim 22, wherein the consumption data are represented at least one of graphically or in the form of text on the external device.

26. A method for controlling a residential unit,
the residential unit having a distributor with at least one load circuit,
at least one load being arranged in each load circuit,
at least one load being individually controllable,
at least one load circuit having means for measuring the power consumed in the load circuit,
the residential unit having a monitoring unit which controls the loads on the basis of predetermined or predeterminable scenes,
the monitoring unit being connected or being able to be connected to a control device and being controlled or being able to be controlled by said control device, individual scenes being selected and the loads in the residential unit being controlled or being able to be controlled accordingly.

27. The method as claimed in claim 26, wherein the monitoring unit being connected or being able to be connected to a control device via the Internet.

28. The method as claimed in claim 26, wherein the power consumption of the load circuits is individually measured and recorded by the monitoring unit, and wherein the monitoring unit assigns the power consumption to the scenes which have been set.

29. The method as claimed in claim 28, wherein consumption data of the residential unit are transmitted from the monitoring unit to the control device.

30. The method as claimed in claim 29, wherein consumption data of the residential unit comprises the power consumption of at least one of the individual load circuits or the individual loads or the individual scenes.

31. The method as claimed in claim 29, wherein the consumption data are represented at least one of graphically or in the form of text on the control device.

32. The method as claimed in claim 26, wherein at least one scene is configured using the control device.

33. A computer program product which can be loaded directly into the internal memory of a digital computer and comprises software sections which are used to carry out the steps recited in claim 16 when the product runs on a computer.

34. A computer program product which can be loaded directly into the internal memory of a digital computer and comprises software sections which are used to carry out the steps recited in claim 26 when the product runs on a computer.

35. A method for equipping or retrofitting residential units, with the result that a method as claimed in claim 16 can be carried out, comprising one or more of the following steps in any desired combination:
installing at least one of controllable switching means in one or more loads or controllable loads,
installing means for measuring consumed power in one or more load circuits,
installing a monitoring unit which is configured in such a manner that the monitoring unit controls the loads on the basis of predetermined or predeterminable scenes and records the power consumption of the load circuits and assigns it to the scenes which have been set.

36. A method for equipping or retrofitting residential units, with the result that a method as claimed in claim 26 can be carried out, comprising one or more of the following steps in any desired combination:
installing at least one of controllable switching means in one or more loads or controllable loads,
installing means for measuring consumed power in one or more load circuits,
installing a monitoring unit which is configured in such a manner that the monitoring unit controls the loads on the basis of predetermined or predeterminable scenes and records the power consumption of the load circuits and assigns it to the scenes which have been set.
